(19) United States
(12) Patent Application Publication
(10) Pub. No.: US 2012/0080668 A1
(43) Pub. Date: Apr. 5, 2012

(54) ORGANIC EL LIGHTING DEVICE AND METHOD OF MANUFACTURING THE SAME

(75) Inventor: Shunichi SEKI, Suwa-shi (JP)

(73) Assignee: SEIKO EPSON CORPORATION, TOKYO (JP)

(21) Appl. No.: 13/245,189

(22) Filed: Sep. 26, 2011

(30) Foreign Application Priority Data
Oct. 5, 2010 (JP) 2010-225432
Jul. 5, 2011 (JP) 2011-148897

(51) Int. Cl. H01L 51/52; H01L 51/56

(52) U.S. Cl. 257/40; 438/29; 257/E51.018; 257/E51.001

(57) ABSTRACT

An organic EL lighting device includes a first electrode which is formed corresponding to each of the plurality of light-emitting portions on a substrate, an organic functional layer which is formed at least in a light-emitting area, a second electrode which is formed at least on the organic functional layer, and a conductive/light-scattering layer as a layer which has a conductive property and a light-scattering property, is formed on the second electrode, and is electrically connected to the second electrode. The conductive/light-scattering layer is formed of a conductive resin binder in which fine particles as transparent conductive fine particles are dispersed.

### BACKGROUND

1. Technical Field

The present invention relates to an organic EL lighting device and a method of manufacturing the organic EL lighting device.

2. Related Art

In recent years, organic EL devices having an electroluminescence (hereinafter, referred to as EL) element have attracted attention as a display device having a self light-emitting element. Organic EL devices have a configuration in which a light-emitting element in which a light-emitting layer made of an organic EL material is sandwiched between a pair of electrodes is provided in a substrate surface. Since the organic EL devices can be used in a display device such as a display or a thin planar light-emitting device, they are attracting attention as a backlight itself or a lighting device.

Organic EL devices are classified into a bottom emission structure which extracts light from the side of a substrate and a top emission structure which extracts light from the side of an opposed substrate such as a sealing substrate or a color filter substrate in accordance with a difference in the light extraction direction from a light-emitting layer. In general, for an electrode on the side where the light is emitted among a pair of electrodes with a light-emitting layer interposed therebetween, a conductive material having translucency, for example, an ITO (indium tin oxide) film or an IZO (indium zinc oxide) film is used.

However, in an organic EL element which is formed in a wide planar area such as a backlight or a lighting device, since an ITO film or an IZO film which is used for a transparent electrode has a larger resistance than a metal film, in-plane unevenness in luminance due to a voltage drop occurs. With regard to such a problem, for example, JP-A-2007-26932 proposes a structure in which a plurality of power-receiving portions are provided on a translucent anode side and an auxiliary wire is formed using the same metal film as a cathode to reduce luminance unevenness due to a voltage drop.

In addition, regarding a light-emitting device which is constituted by a plurality of pixels as in a color display in which a white-light-emitting organic EL layer and a color filter are combined with each other, a method is proposed in which an auxiliary wire (cathode) is formed on a barrier which is formed corresponding to a pixel to suppress luminance unevenness due to a voltage drop.

When a low-resistance auxiliary wire is provided as in JP-A-2007-26932, in-plane luminance unevenness due to a voltage drop can be suppressed to some extent. However, when an in-plane light-emission defect occurs, not only does light-emission unevenness due to a local non-light emitting area occur, most areas may not emit the light in accordance with the progression of the defect, whereby defective products may be produced. With regard to the light-emission defect, the same problem also occurs in a light-emitting device which is constituted by a plurality of light-emitting pixels and has an auxiliary cathode formed on a barrier as in JP-A-2007-227129.

### SUMMARY

An advantage of some aspects of the invention is to provide an organic EL lighting device which suppresses the in-plane luminance unevenness due to a voltage drop and the generation of a local non-light emitting area due to a light-emission defect, and a method of manufacturing the organic EL lighting device.

The invention is contrived to solve at least a portion of the above-described problems and can be realized by the following aspects or applications.

According to an aspect of the invention, an organic EL lighting device having an organic functional layer which is formed corresponding to a plurality of light-emitting portions on a substrate, includes: a first electrode which is formed corresponding to each of the plurality of light-emitting portions; the organic functional layer which is formed at least in a light-emitting area; a second electrode which is formed at least on the organic functional layer; and a layer which has a conductive property and a light-scattering property, is formed on the second electrode, and is electrically connected to the second electrode.

In the organic EL lighting device according to the aspect of the invention, since the layer which has a conductive property and a light-scattering property and is electrically connected to the second electrode on the second electrode acts as an auxiliary electrode, a reduction in luminance due to a voltage drop can be suppressed and in-plane luminance unevenness can be prevented. Furthermore, since the layer acting as the auxiliary electrode has a light scattering property, the light from a light-emitting portion which is not a defect is scattered and emitted even when a non-light emitting area due to a light-emission defect is generated. Accordingly, it is possible to provide an organic EL lighting device having no visual defect or local unevenness.

In addition, in the organic EL lighting device according to the aspect of the invention, it is preferable that the second electrode have light permeability.

The light can be emitted from the second electrode via the scattering layer, and it is possible to provide an organic EL lighting device which uniformly emits light without visual light-emission unevenness.

In addition, in the organic EL lighting device according to the aspect of the invention, it is preferable that the layer which has a conductive property and a light-scattering property include at least one or more kinds of fine particles.

Since the layer which has a conductive property and a light-scattering property includes fine particles, the layer has a light-scattering property, and it is possible to uniformize the visual in-plane light emission.

In addition, in the organic EL lighting device according to the aspect of the invention, it is preferable that the fine particles be conductive.

Since the fine particles are conductive, the light-scattering layer acts as an auxiliary electrode of the second electrode, and it is possible to suppress a reduction in in-plane luminance due to a voltage drop.

In addition, in the organic EL lighting device according to the aspect of the invention, it is preferable that the fine particles be transparent conductive oxide fine particles.

Using one kind of fine particles, a layer which has light permeability, a conductive property and a light-scattering property can be formed on the second electrode. Accordingly, it is possible to provide an organic EL lighting device which uniformly emits light.

In addition, in the organic EL lighting device according to the aspect of the invention, it is preferable that the fine particles be metal fine particles.

By using metal fine particles, a low-resistance auxiliary electrode can be formed, a voltage drop is effectively suppressed, and the light can be uniformly emitted.

In addition, in the organic EL lighting device according to the aspect of the invention, it is preferable that the fine particles be light-permeable.

Since light-permeable fine particles are included, a layer having a light-scattering property can be formed, and even when a light-emission defect is present, it is possible to provide visually uniform light emission.

In addition, in the organic EL lighting device according to the aspect of the invention, it is preferable that the fine particles have a size of 1 nm to 100 nm.

It is not preferable that the size be significantly smaller than 1 nm because the size control becomes difficult, and it is not preferable that the size be larger than 100 nm because the contact area between the fine particles is reduced and a high-resistance auxiliary electrode is not obtained.

In addition, in the organic EL lighting device according to the aspect of the invention, it is preferable that the fine particles be dispersed in a conductive resin.

Since a conductive resin is used as a binder and the fine particles are included therein, a light-scattering auxiliary electrode layer with a suppressed resistance can be formed. Furthermore, an auxiliary electrode layer can be efficiently formed so as to be uniformly formed even on the irregularities on the substrate.

In addition, in the organic EL lighting device according to the aspect of the invention, it is preferable that the layer which has a conductive property and a light-scattering property have a thickness of 0.1 μm to 10 μm.

Since the resistance increases when the thickness is smaller than 0.1 μm, the layer cannot act as an auxiliary electrode which suppresses a voltage drop. In addition, when the thickness is larger than 10 μm, the light permeability deteriorates and the brightness is lowered.

In addition, it is preferable that the organic EL lighting device according to the aspect of the invention further include a barrier which partitions the plurality of first electrodes.

Since the barrier is provided, the light-emitting portion can be effectively divided into a plurality of areas. The above-described barrier is preferably formed of an insulating material such as organic matter or oxide. The parasitic capacity can be reduced by forming an insulating barrier, and when the light-emitting portions are to be independently driven, the driving element and the wire can be provided under the barrier.

In addition, in the organic EL lighting device according to the aspect of the invention, it is preferable that the barrier have an opening portion exposing the first electrode and be formed to partially overlap the first electrode in plan view.

When the organic functional layer is formed on the first electrodes partitioned by the barriers, the coatability of the organic functional layer in a taper portion of the barrier is generally poor. Accordingly, it becomes a cause of a short circuit between the first and second electrodes and a light-emission defect easily occurs. Since the barrier is formed to partially overlap with the first electrode, it is possible to provide a lighting device which has no defect and uniformly emits light. Accordingly, the taper angle of the barrier is preferably small, and more preferably equal to or smaller than 45 degrees.

In addition, in the organic EL lighting device according to the aspect of the invention, it is preferable that the organic functional layer be formed at least in the light-emitting area and divided by the barrier.

By forming the organic functional layer in a discontinuous manner in the plane, the progression of the occurring light-emission defect is suppressed to light-emitting areas which are partitioned by minimum units of barriers.

In addition, by using barriers having liquid repellency, the organic functional layer can be formed by a pattern applying method such as an ink jet method, and it is possible to easily manufacture an organic EL lighting device at a low cost. Furthermore, not only a single color light-emitting material, but also materials which emit different colors of light, for example, materials of three RGB primary colors can be painted to make a white color. It is possible to provide an organic EL lighting device which can change the color of light by adjusting the strength for each of the light-emitting areas (pixels) for each color.

According to another aspect of the invention, a method of manufacturing an organic EL lighting device having an organic functional layer which is formed corresponding to a plurality of light-emitting portions on a substrate includes: forming a first electrode for each of the plurality of light-emitting portions; forming the organic functional layer at least in a light-emitting area; forming a second electrode at least on the organic functional layer; and forming a layer which has a conductive property and a light-scattering property so as to be electrically connected to the second electrode on the second electrode.

In the method of manufacturing an organic EL lighting device according to the aspect of the invention, the layer which has a conductive property and a light-scattering property is formed so as to be electrically connected to the second electrode on the second electrode, that is, a light-scattering auxiliary electrode can be formed, and it is possible to manufacture an organic EL lighting device excellent in quality, which suppresses luminance unevenness due to a voltage drop and in which a light-emission defect is made less visually noticeable even when the light-emission defect is present.

In addition, in the method of manufacturing an organic EL lighting device according to the aspect of the invention, it is preferable that the layer which has a conductive property and a light-scattering property be formed by an applying method using a composition including at least a conductive material.

It is possible to employ an applying method using a composition in which fine particles which are conductive or transparent are dispersed in, for example, a conductive high-molecular-weight material, and it is possible to easily manufacture an organic EL lighting device at a low cost.

### BRIEF DESCRIPTION OF THE DRAWINGS

The invention will be described with reference to the accompanying drawings, wherein like numbers reference like elements.

FIG. 1 is an equivalent circuit schematic of an organic EL lighting device according to a first embodiment.

FIG. 2 is a plan view showing a lighting portion of the organic EL lighting device according to the first embodiment.

FIG. 3 is a cross-sectional view showing a configuration of the organic EL lighting device according to the first embodiment.

FIG. 4 is a cross-sectional view showing the configuration of the organic EL lighting device according to the first embodiment.

FIG. 5 is a cross-sectional view showing a configuration of an organic EL lighting device according to a second embodiment.

FIG. 6 is a cross-sectional view showing a configuration of an organic EL lighting device according to a third embodiment.

FIG. 7 is a perspective view showing an appearance of a lighting stand having the organic EL lighting device according to the invention.

FIG. 8 is a perspective view showing an appearance of a personal computer having the organic EL lighting device according to the invention.

FIG. 9 is a perspective view showing an appearance of a mobile phone having the organic EL lighting device according to the invention.

### DESCRIPTION OF EXEMPLARY EMBODIMENTS

Hereinafter, embodiments of the invention will be described with reference to the drawings. This embodiment relates to an organic EL lighting device which uses a white-light-emitting organic EL material for a light-emitting layer and a method of manufacturing, for example, an organic EL lighting device having a so-called top emission structure.

In the drawings shown as follows, the scale and the like are appropriately changed for easy understanding of fine portions in detail, and thus the actual sizes are different from the sizes in the drawings.

### First Embodiment

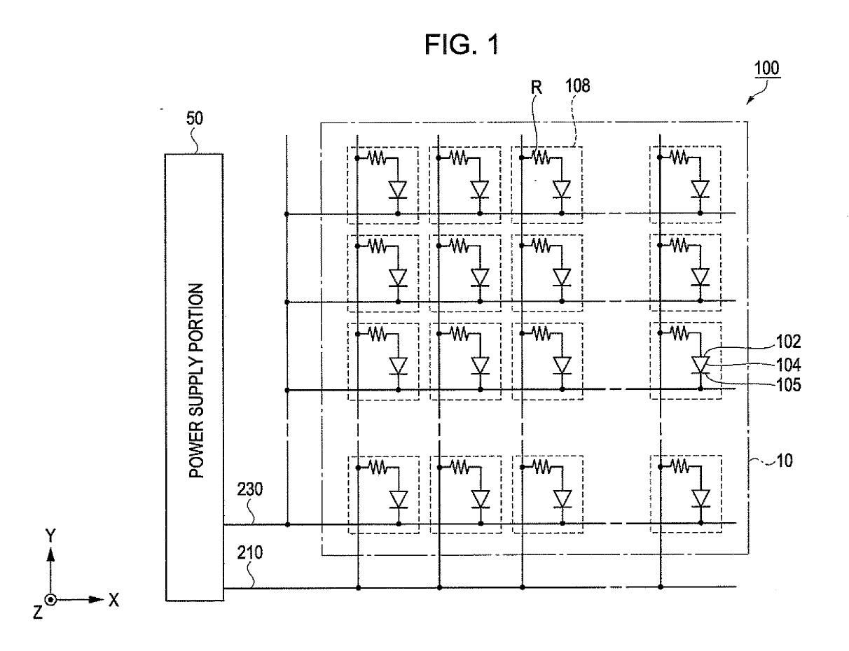

FIG. 1 is an equivalent circuit schematic of an organic EL lighting device according to a first embodiment.

As shown in FIG. 1, an organic EL lighting device 100 of this embodiment has a lighting portion 10 and a power supply portion 50.

In the lighting portion 10, light-emitting portions (organic EL elements) 108 are formed in M columns×N rows (M and N are natural numbers equal to or larger than 1). Each of the plurality of light-emitting portions 108 is configured so that a first electrode 102, an organic functional layer 104 including a light-emitting layer, and a second electrode 105 are connected in series. In addition, a bleeder resistance R is connected to each light-emitting portion 108.

The power supply portion 50 supplies a high potential VH to the first electrode 102 via a first power wire 210, and supplies a low potential VL to the second electrode 105 via a second power wire 230. That is, the first electrode 102 functions as an anode and a second electrode 105 functions as a cathode. The organic functional layer 104 emits light in accordance with the amount of current flowing between the first electrode 102 and the second electrode 105.

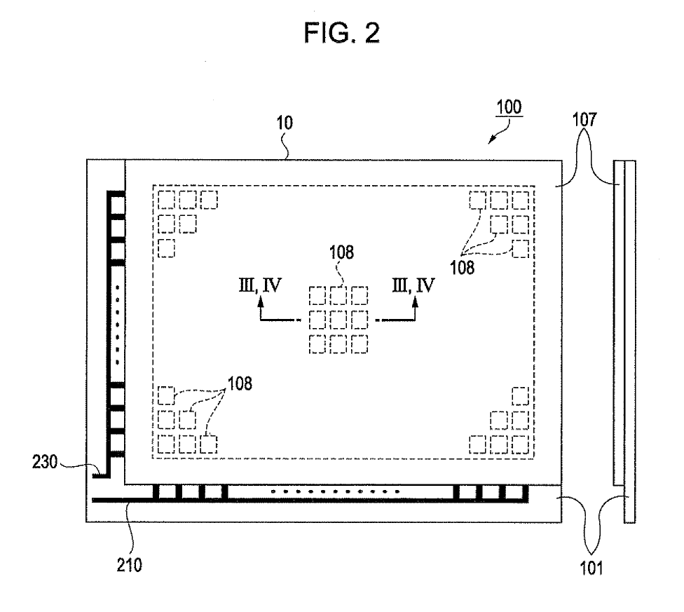

FIG. 2 is a plan view showing the lighting portion of the organic EL lighting device according to the first embodiment. As shown in FIG. 2, the lighting portion 10 of the organic EL lighting device 100 has a substrate 101 in which the plurality of light-emitting portions 108 are arranged in a matrix, and a sealing layer 107 which seals the plurality of light-emitting portions 108.

The substrate 101 is slightly larger than the sealing layer 107. The above-described first power wire 210 and second power wire 230 are partially exposed in a terminal portion protruding from the sealing layer 107, and the terminal portion can be electrically connected to the above-described power supply portion 50.

The first electrode 102 and the organic functional layer 104 are formed in one to one correspondence to each of the plurality of light-emitting portions 108. In addition, the second electrode 105 is formed to be common to all the M×N of light-emitting portions 108.

In addition, although omitted in the drawing, a transparent interlayer insulating film which shields the first electrodes 102 is formed on the substrate 101, and a bleeder resistance R which is electrically connected to each of the plurality of first electrodes 102 is formed on the interlayer insulating film. Accordingly, the first electrode 102 is supplied with a high potential VH from the power supply portion 50 via the bleeder resistance R and the first power wire 210. The bleeder resistance R can be made of, for example, polysilicon.

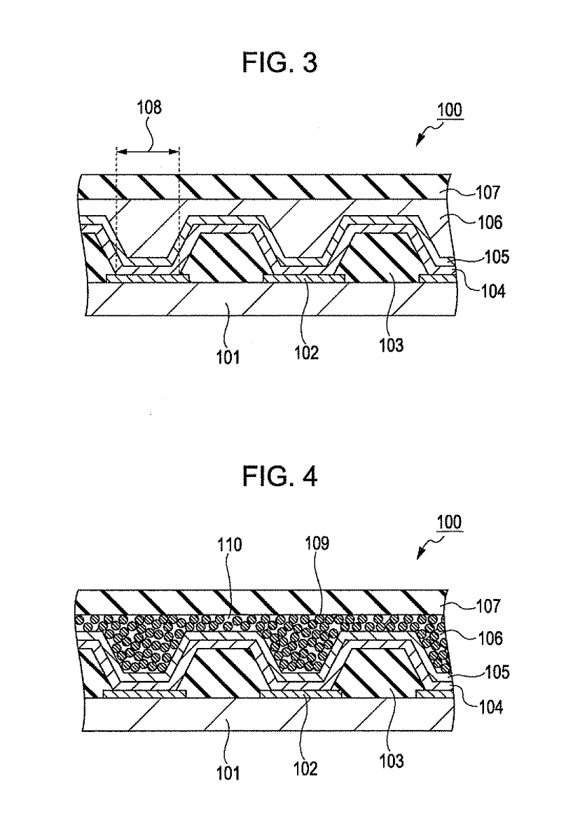

Next, a structure of the light-emitting portion of this embodiment will be described with reference to FIGS. 3 and 4.

FIGS. 3 and 4 are cross-sectional views showing a structure of the light-emitting portion cut by the line III-III, IV-IV of FIG. 2.

As shown in FIG. 3, the organic EL lighting device 100 has the substrate 101, the first electrodes 102 which are formed and patterned corresponding to the light-emitting areas on the substrate 101, barriers 103 which are formed to overlap outer edge portions of the first electrodes 102 in plan view and to partition the first electrodes 102, the organic functional layer 104 which is stacked over the first electrodes 102 and the barriers 103, and the second electrode 105. In addition, the organic EL lighting device 100 has a conductive/light-scattering layer 106 as a layer of the invention which is formed to be brought into contact with the second electrode 105 and has a conductive property and a light-scattering property, and the sealing layer 107 for suppressing the intrusion of oxygen and moisture to the organic functional layer 104.

The substrate 101 may use a light-permeable base material such as glass, quartz, or plastic, or an opaque base material such as insulating ceramic or silicon.

The light-emitting portion (organic EL element) 108 is constituted by the organic functional layer 104, the first (anode) and second (common cathode) electrodes 102 and 105 which hold the organic functional layer 104 therebetween, the conductive/light-scattering layer 106 which is formed on the second electrode 105, and the sealing layer 107.

ITO, IZO, or molybdenum oxide can be used as a forming material for the first electrode 102. In the case of the top emission structure which extracts light from the second electrode 105 as in this embodiment, a reflective layer (not shown) such as aluminum (Al) is formed between the first electrode 102 and the substrate 101.

In addition, although not shown in the drawing, the, organic functional layer 104 has a lamination structure of a hole injection/transport layer, a light-emitting layer, an electron injection layer, and/or an electron transport layer.

A polythiophene derivative which is a mixture of polyethylene dioxythiophene and polystyrene sulfonate, an aromatic amine compound, copper phthalocyanine or the like can be used as a forming material for the hole injection/transport layer.

A known low-molecular-weight material capable of emitting white fluorescence or phosphorescence can be used as a forming material for the light-emitting layer. Examples thereof include anthracene, pyrene, 8-hydroxyquinoline aluminum, bis(styryl)anthracene derivatives, tetraphenyl butadiene derivatives, coumarin derivatives, oxadiazole derivatives, distyrylbenzene derivatives, pyrrolopyridine derivatives, perinone derivatives, cyclopentadiene derivatives, and thiadiazolopyridine derivatives, and it is also possible to use these low-molecular-weight materials doped with rubrene, a quinacridone derivative, a phenoxazone derivative, DCM, DCJ, perinone, a perylene derivative, a coumarin derivative, a diazaindacene derivative or the like. In addition, a high-molecular-weight material such as a white-light-emitting polyfluorene derivative can also be used.

An oxadiazole derivative, a thiadiazole derivative, a quinoxaline derivative, 8-hydroxyquinoline aluminum, or the like can be used as a forming material for the electron injection/transport layer.

The forming material for the second electrode 105 is required to have a transmission property. An example thereof is formed so that a low work function alkali metal or alkaline earth metal such as lithium (Li), calcium (Ca) or magnesium (Mg), or a fluoride thereof is formed in a thickness of several nanometers, and a metal having oxidation resistance and a high conductive property such as gold (Au), silver (Ag) or Al is stacked or formed as an alloy thereon in a thickness of several tens of nanometers or less. Otherwise, the above-described metal may be formed in a thickness of about several nanometers and transparent ITO or the like may be formed thereon.

The barrier 103 is made of a polyimide or acrylic resin which is an insulator material, or a silicon compound of SiO₂ or SiN. The barrier 103 has a function of a bank to define each light-emitting area. The barrier 103 is formed to have an opening portion to partition and expose the first electrode 102 so as to partially overlap the first electrode 102. The substantial light-emitting area is specified by the opening portion.

In addition, when the organic functional layer 104 is formed by a deposition method, the taper angle of the barrier 103 is preferably equal to or smaller than 45 degrees in order to suppress poor throwing power due to unevenness.

The sealing layer 107 is configured to suppress the intrusion of oxygen and moisture to the organic functional layer 104. The sealing layer 107 may have translucency, and is preferably, for example, a laminate of silicon oxides such as SiO₂ and SiON or a laminate of a silicon oxide and organic matter.

Next, the conductive/light-scattering layer 106 will be described with reference to FIG. 4. FIG. 4 is a cross-sectional view showing the organic EL lighting device 100 according to the first embodiment in more detail.

The conductive/light-scattering layer 106 shown in FIG. 3 is constituted by light-permeable fine particles 109 and a conductive resin binder 110 as shown in FIG. 4. Oxide fine particles such as SiO₂, TiO₂, or ITO can be used as the light-permeable fine particles 109. A material doped in a highly-conductive polythiophene derivative which is represented by a mixture of polyethylene dioxythiophene and polystyrene sulfonate can be used as the resin binder 110.

Since the light-permeable fine particles 109 are dispersed in the conductive resin binder 110, the conductive/light-scattering layer 106 can function as a light-scattering auxiliary electrode. In order to obtain a lower-resistance auxiliary electrode, ITO fine particles are more preferably used as the fine particles 109.

The fine particles 109 may have a size to effectively scatter white light. However, the size can be controlled and is preferably in the range of 1 nm to 100 nm when considering that the contact area between the fine particles is not reduced.

Furthermore, The thickness of the conductive/light-scattering layer 106 is preferably in the range of 0.1 μm to 10 μm when considering that the resistance does not increase and a transmittance is not lowered. In addition, by dispersing the fine particles 109 in the resin binder 110, the conductive/light-scattering layer 106 having a uniform thickness can be formed even on the uneven structure such as the barrier 103.

Although not shown in FIGS. 3 and 4, each first electrode 102 is connected to the first power wire 210 via the above-described bleeder resistance R. This bleeder resistance R uses a resistance of kiloohms to megaohms so that all other light-emitting areas connected to the same first power wire 210 are not short-circuited and are lighted when a short circuit occurs in a light-emitting area. In addition, the first electrode 102 may be configured to be connected to a thin-film transistor so that active driving is possible for each light-emitting area.

At that time, the bleeder resistance R and the thin-film transistor can be formed under the barrier 103. Otherwise, in the case of the top emission structure as in this embodiment, the bleeder resistance R and the thin-film transistor may be formed in a lower portion of the first electrode 102 on the substrate 101.

Next, a method of manufacturing the organic EL lighting device 100 described in the first embodiment will be described. First, a thin film for the first electrode (anode) 102 made of ITO or the like is formed in a film thickness of 50 nm by, for example, a sputtering method on an upper surface of the substrate 101. Then, a pattern is formed by a photolithographic process and thus the first electrodes 102 are formed.

Next, a photosensitive acrylic resin as a forming material for the barrier 103 is applied to the upper surfaces of all the first electrodes 102. Then, similarly, the barriers 103 having a thickness of about 1 μm to 2 μm and a taper angle of 30 degrees are formed by a photolithographic process so as to open one end of the first electrode 102.

Next, on the opening portions of the first electrodes 102 and the barriers 103, the white-light-emitting organic functional layer 104 is formed in a total thickness of 130 nm by a vacuum heating deposition method in order of the hole injection/transport layer, the light-emitting layer, and the electron transport layer. This film thickness is not limited to this. For example, the film thickness can be set in the range of 50 nm to 200 nm, and is preferably in the range of 100 nm to 150 nm.

Next, as the second electrode 105, a metal fluoride, for example, LiF is formed in a film thickness of 1 nm on the organic functional layer 104 by a deposition method, and then a MgAg layer having a thickness of 10 nm is formed by a deposition method. Next, a composition in which ITO fine particles having an average particle size of 10 nm are dispersed in a mixture solution of polyethylene dioxythiophene and polystyrene sulfonate is formed in a thickness of 10 μm on an entire upper surface of the second electrode 105 by an applying method, for example, a spin coat method, a slit coat method, or an ink jet method. Since the composition includes the solvent, heating and drying at 100° C. under a vacuum of 1 Torr or less are preferably performed after the application to form the conductive/light-scattering layer 106.

Next, SiON and organic matter are alternately stacked so as to cover the conductive/light-scattering layer 106 over all of the light-emitting areas, and thus the sealing layer 107 is formed. In place of them, ITO may be used. SiON and ITO are formed by a sputtering method, a plasma coating method or the like.

Since the conductive/light-scattering layer 106 having a conductive property and a light-scattering property is provided on the second electrode 105 in the organic EL lighting device 100 having the above-described configuration, luminance unevenness due to a voltage drop is not shown. In addition, even when a non-light emitting area is present, the light from the surrounding light-emitting portions 108 is scattered and ejected by the conductive/light-scattering layer 106, and thus unevenness such as local non-light emission is not visually observed. Accordingly, it is possible to obtain the organic EL lighting device 100 which uniformly emits the light in the plane.

### Second Embodiment

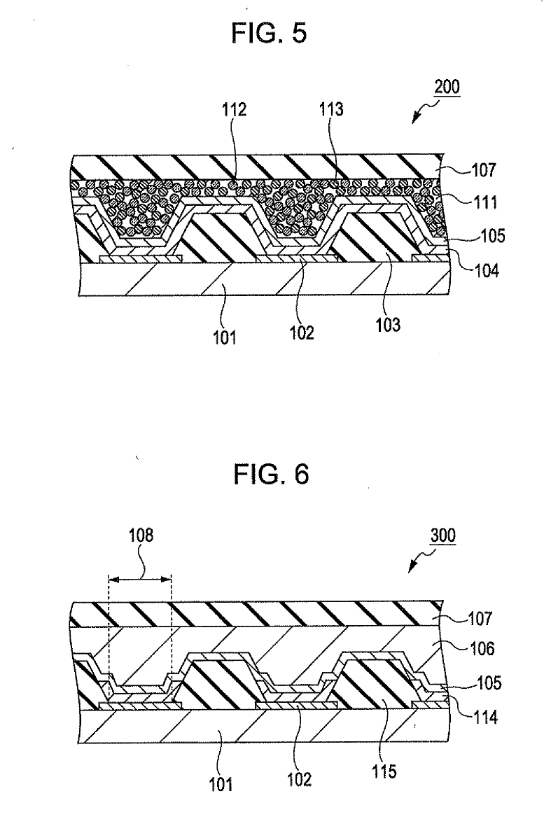

FIG. 5 is a cross-sectional view showing a configuration of an organic EL lighting device according to a second embodiment of the invention.

As shown in FIG. 5, an organic EL lighting device 200 of the second embodiment has the same configuration as in the first embodiment, except that a conductive/light-scattering layer 111 is constituted by two kinds of fine particles. Accordingly, the same constituent elements will be denoted by the same reference symbols and the detailed description thereof will be omitted.

The conductive/light-scattering layer 111 of the second embodiment is formed of transparent fine particles 112 and conductive fine particles 113. As in the first embodiment, light-permeable fine particles such as SiO₂, TiO₂ or ITO are used as the transparent fine particles 112, and thus the light-scattering property can be given to the conductive/light-scattering layer 111.

Furthermore, since the conductive/light-scattering layer 111 includes the conductive fine particles 113, the resistance value is effectively reduced and functioning as an auxiliary electrode is possible. Highly-conductive metal fine particles having reflectivity such as Ag (silver) or Au (gold) may be used as the conductive fine particles 113. Using the above-described configuration, a more effective conductive/light-scattering layer 111 can be formed, a voltage drop can be suppressed, and a non-light emitting area can be made less visually noticeable by scattering. Accordingly, it is possible to obtain the organic EL lighting device 200 which uniformly emits the light in the plane.

In order to further reduce the resistance of the conductive/light-scattering layer 111, transparent conductive oxide fine particles such as ITO are more preferably used as the light-permeable fine particles.

Next, a method of manufacturing the organic EL lighting device 200 of the second embodiment will be described. As in the first embodiment, a composition in which the transparent fine particles 112 and the conductive fine particles 113 are dispersed in a solvent is formed in a thickness of 10 μm by an applying method, for example, a spin coat method, a slit coat method, or an ink jet method. Since the composition includes the solvent, heating and drying at 100° C. under a vacuum of 1 Torr or less are preferably performed after the application to form the conductive/light-scattering layer 111. Using the application method, the organic EL lighting device 200 can be easily manufactured at a low cost.

### Third Embodiment

FIG. 6 is a cross-sectional view showing a configuration of an organic EL lighting device according to a third embodiment of the invention.

As shown in FIG. 6, in an organic EL lighting device 300 of the third embodiment, an organic layer 114 is divided by barriers 115. The other constituent elements are the same as in the first and second embodiments, but the description will be given using the constituent elements in the first embodiment as an example. The organic functional layer 114 is not formed in a continuous manner but formed independently for each of the light-emitting portions 108. Accordingly, deterioration when a defect occurs can be suppressed in units of the light-emitting areas in which the organic functional layer 114 is formed.

In general, in the case of a light-emission defect which occurs in an intrusion route of moisture and oxygen, the moisture and oxygen intruding through this route spread via the organic functional layer, and thus the light-emission defect also widens. Accordingly, when the non-light emission area generated by the light-emission defect is large, it is difficult to obtain visual uniformity with a scattering effect even when a light-scattering layer is provided on a light emission side.

However, by applying the configuration of this embodiment, the light-emission defect can be prevented in units of the light-emitting areas. Therefore, the light-emission defect can be made less noticeable by the conductive/light-scattering layer 106 without an increase in the non-light emitting area.

Accordingly, using the above-described configuration, the organic EL lighting device 300 which has high reliability and light-emission uniformity not damaged even when stored for a long time can be provided.

Next, a method of manufacturing the organic EL lighting device 300 of the third embodiment will be described. In this third embodiment, a mask is used in the formation of the organic functional layer 114 by a deposition method. The organic functional layer 114 is formed on an opened portion of the mask, that is, at least on a portion opened by the barrier 115 of the upper surface of the first electrode 102, and the organic functional layer 114 is not formed on the upper surface of the barrier 115. The second electrode 105 and other constituent elements are formed in the same manner as in the first and second embodiments.

Using the above-described method, the organic EL lighting device 300 which has high reliability and light-emission uniformity not damaged even when stored for a long time can be provided.

In addition, the forming method is not limited to the deposition method, and the organic functional layer 114 may be formed at least on the portion opened by the barrier 115 of the first electrode 102 by using an applying method such as an ink jet method capable of performing patterning.

At that time, in order to accurately paint the organic functional layer material, it is desirable to give liquid repellency to the barrier 115. The barrier 115 may be formed by using an acrylic resin or a polyimide resin including a fluorine compound through a photolithographic process, or the barrier 115 formed of organic matter may be subjected to a plasma process using a fluorine-based gas to give liquid repellency to the barrier 115.

In any method, in a skirt portion of the barrier 115 on the first electrode 102, the film thickness of the organic functional layer 114 is large and a short circuit easily occurs between the first and second electrodes 102 and 105. Accordingly, when a pattern is formed by an ink jet method or the like, an insulating layer barrier formed of inorganic matter such as SiO₂ is preferably formed and a barrier 115 formed of organic matter is preferably formed thereon. That is, a two-layered barrier is preferably formed.

In addition, when the organic functional layer 114 is formed by a deposition method using a mask or an ink jet painting method, the same white-light-emitting material may be used to form the organic functional layer 114, or different materials of three RGB primary colors may be patterned to form the organic functional layer 114. When the organic functional layer 114 is formed using a different light-emitting material for each light-emitting area, it is possible to provide the organic EL lighting device 300 which can adjust the hue of white and a color rendering property when changing the respective driving conditions.

### Applications

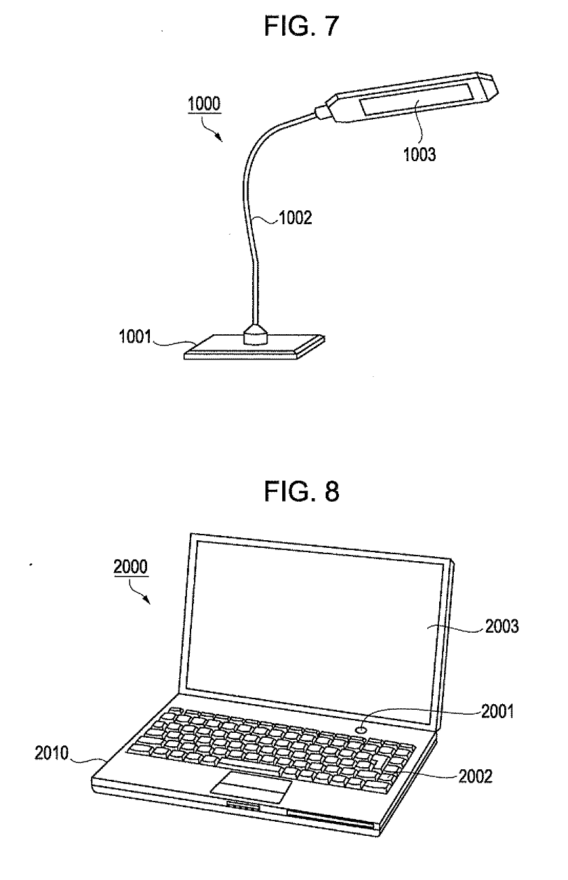

Next, electronic devices to which the organic EL lighting device of the above-described embodiment is applied will be described. FIGS. 7 to 9 show the forms of electronic devices to which the organic EL lighting device is applied.

FIG. 7 is a perspective view showing an appearance of a lighting stand having the organic EL lighting device according to the invention. A lighting stand 1000 has a base 1001, a connecting portion 1002, and a lighting device 1003. Any of the organic EL lighting devices 100, 200, and 300 of the above-described embodiments is employed as the lighting device 1003.

FIG. 8 is a perspective view showing an appearance of a personal computer having the organic EL lighting device according to the invention. A personal computer 2000 includes a main body portion 2010 in which a power switch 2001 and a keyboard 2002 are installed, and a display portion 2003 which displays various images. The display portion 2003 is constituted by a liquid crystal device, and any of the planar organic EL lighting devices 100, 200, and 300 of the above-described embodiments is employed as a backlight of this liquid crystal device.

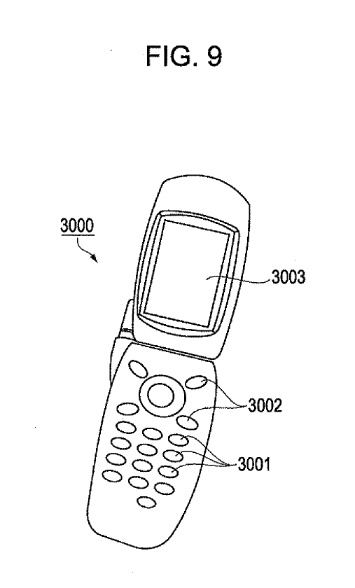

FIG. 9 is a perspective view showing an appearance of a mobile phone having the organic EL lighting device according to the invention. A mobile phone 3000 has a plurality of operating buttons 3001, scroll buttons 3002, and a display portion 3003 which displays various images. A screen which is displayed on the display portion 3003 is scrolled by operating the scroll buttons 3002.

The display portion 3003 is constituted by a liquid crystal device, and any of the planar organic EL lighting devices 100, 200, and 300 of the above-described embodiments is employed as a backlight of this liquid crystal device.

Examples of the electronic devices to which the organic EL lighting device according to the invention is applied include digital still cameras, televisions, video cameras, car navigation devices, pagers, electronic notebooks, electronic papers, calculators, word processors, work stations, video phones, POS terminals, printers, scanners, copiers, video players, devices having a touch panel and the like, other than the electronic devices shown in FIGS. 7 to 9.

The invention is not limited to the above-described embodiments and can be appropriately changed without departing from the gist or idea of the invention which is read from the claims and the entire specification. An organic EL lighting device and a method of manufacturing the organic EL lighting device with such a change are also included in the technical scope of the invention. Various modified examples other than the above-described embodiments are considered. Hereinafter, a modified example will be described.

### MODIFIED EXAMPLE 1

The conductive/light-scattering layer 106 of the organic EL lighting device 100 of the first embodiment may have a configuration in which in place of the light-permeable fine particles 109, highly-conductive metal fine particles having reflectivity such as Ag (silver) or Au (gold) are dispersed in the resin binder 110.

This application claims priority from Japanese Patent Applications No. 2010-225432 filed in the Japanese Patent Office on Oct. 5, 2010 and No. 2011-148897 filed in the Japanese Patent Office on Jul. 5, 2011, the entire disclosure of which is hereby incorporated by references in its entirely.

What is claimed is:

1. An organic EL lighting device having an organic functional layer which is formed corresponding to a plurality of light-emitting portions on a substrate, the device comprising:
a first electrode which is formed corresponding to each of the plurality of light-emitting portions;
the organic functional layer which is formed at least in a light-emitting area;
a second electrode which is formed at least on the organic functional layer; and
a layer which has a conductive property and a light-scattering property, is formed on the second electrode, and is electrically connected to the second electrode.

2. The organic EL lighting device according to claim 1,
wherein the second electrode has light permeability.

3. The organic EL lighting device according to claim 1,
wherein the layer which has a conductive property and a light-scattering property includes at least one or more kinds of fine particles.

4. The organic EL lighting device according to claim 3,
wherein the fine particles are conductive.

5. The organic EL lighting device according to claim 3,
wherein the fine particles are transparent conductive oxide fine particles.

6. The organic EL lighting device according to claim 4,
wherein the fine particles are metal fine particles.

7. The organic EL lighting device according to claim 3,
wherein the fine particles are light-permeable.

8. The organic EL lighting device according to claim 3,
wherein the fine particles have a size of 1 nm to 100 nm.

9. The organic EL lighting device according to claim 3,
wherein the fine particles are dispersed in a conductive resin.

10. The organic EL lighting device according to claim 1,
wherein the layer which has a conductive property and a light-scattering property has a thickness of 0.1 μm to 10 μm.

11. The organic EL lighting device according to claim 1, further comprising:
a barrier which partitions the plurality of first electrodes.

12. The organic EL lighting device according to claim 11,
wherein the barrier has an opening portion exposing the first electrode and is formed to partially overlap the first electrode in plan view.

13. The organic EL lighting device according to claim 1,
wherein the organic functional layer is formed at least in the light-emitting area and divided by the barrier.

14. A method of manufacturing an organic EL lighting device having an organic functional layer which is formed corresponding to a plurality of light-emitting portions on a substrate, the method comprising:
forming a first electrode for each of the plurality of light-emitting portions;
forming the organic functional layer at least in a light-emitting area;
forming a second electrode at least on the organic functional layer; and
forming a layer which has a conductive property and a light-scattering property so as to be electrically connected to the second electrode on the second electrode.

15. The method of manufacturing an organic EL lighting device according to claim 14,
wherein the layer which has a conductive property and a light-scattering property is formed by an applying method using a composition including at least a conductive material.
